(19) United States
(12) Patent Application Publication
(10) Pub. No.: US 2010/0213952 A1
(43) Pub. Date: Aug. 26, 2010

(54) Methods and Apparatuses for Determining Charging Current in Electrical Power Systems

(76) Inventor: Anthony Locker, Cincinnati, OH (US)

Correspondence Address: DINSMORE & SHOHL LLP, 1900 CHEMED CENTER, 255 EAST FIFTH STREET, CINCINNATI, OH, 45202, US

(21) Appl. No.: 12/710,013

(22) Filed: Feb. 22, 2010

Related U.S. Application Data
(60) Provisional application No. 61/154,206, filed on Feb. 20, 2009.

(51) Int. Cl. G01R 27/26

(52) U.S. Cl. 324/658

(57) ABSTRACT

A method and apparatus are disclosed for determining a system charging current in an electrical power system having three phases, a ground, a neutral, and a neutral resistor electrically coupling the neutral to the ground. The method comprises: measuring a line voltage of each phase; measuring a line-to-neutral voltage of each phase; determining a charging capacitance of each phase based on the line voltage of each phase, the line-to-neutral voltage of each phase, a frequency of the electrical power system, and a value of the neutral resistor; determining a phase charging current for each phase of the electrical power system based on the charging capacitance of each phase, the line voltage of each phase, and the frequency of the electrical power system; and determining the system charging current based on the phase charging current for each phase.

### CROSS REFERENCE TO RELATED APPLICATIONS

This patent application claims the benefit of U.S. Provisional Application 61/154,206, filed on Feb. 20, 2009. This application is related to U.S. Patent Application (Docket No. LCK 0002 PA) filed Feb. 22, 2010, but does not claim priority thereto.

### TECHNICAL FIELD

The present disclosure generally relates to methods and apparatuses for determining charging current in electrical power systems and, more particularly, for determining the system charging current in three-phase electrical power systems.

### BACKGROUND

As background, three-phase electrical power systems are often used to distribute electrical power throughout many different types of facilities, including office buildings as well as manufacturing plants. The electrical power may be used for a variety of loads, including but not limited to lighting systems, HVAC (heating, ventilating, and air conditioning) systems, and various types of machines used in manufacturing. In most cases, the amount of electrical current used by a particular load is approximately equal for each of the three phases of the electrical power system. However, stray capacitance inherent in the electrical wiring and/or the load may cause a “charging current” in the system, which may continuously be present and independent of the load current. This system charging current may become unbalanced (i.e., not the same for each of the three phases) and, if so, can appear as a neutral current. Furthermore, the system charging current may vary over time as changes are made to the wiring and/or load.

Faults may also occur in the electrical power system which may be the result of improper wiring, damaged wiring, or electrical failures in the load. These faults may also cause an imbalance in the phase currents which, in some cases, may be difficult to distinguish from the charging current inherent in the system. In some systems, the charging current may cause transient over-voltages and/or false operations that result in a loss of power. Thus, alternative methods and apparatuses are needed which can continuously measure the system charging current and distinguish between changes in the system charging current and actual faults in the electrical power system.

### SUMMARY

In one embodiment, a method for determining a system charging current in an electrical power system having three phases, a ground, a neutral, and a neutral resistor electrically coupling the neutral to the ground comprises: measuring a line voltage of each phase of the electrical power system, wherein the line voltage is measured with respect to the ground; measuring a line-to-neutral voltage of each phase of the electrical power system, wherein the line-to-neutral voltage is measured with respect to the neutral; determining a charging capacitance of each phase of the electrical power system based on the line voltage of each phase, the line-to-neutral voltage of each phase, a frequency of the electrical power system, and a value of the neutral resistor; determining a phase charging current for each phase of the electrical power system based on the charging capacitance of each phase, the line voltage of each phase, and the frequency of the electrical power system; and determining the system charging current based on the phase charging current for each phase.

In another embodiment, an apparatus for determining a system charging current in an electrical power system having three phases, a ground, a neutral, and a neutral resistor electrically coupling the neutral to the ground comprises an input module and a processor, wherein: the input module is configured to be electrically coupled to each phase of the electrical power system, the ground, and the neutral or a neutral current sensor such that the input module: measures a line voltage of each phase of the electrical power system, wherein the line voltage is measured with respect to the ground, and measures a neutral voltage, wherein the neutral voltage is measured with respect to the ground, or measures a neutral current based on the neutral current sensor; the input module is electrically coupled to the processor such that the processor reads the line voltage of each phase and the neutral voltage or the neutral current; and the processor determines: the neutral voltage based on the neutral voltage measured from the input module or based on the neutral current and a value of the neutral resistor; a line-to-neutral voltage of each phase of the electrical power system, wherein the line-to-neutral voltage is measured with respect to the neutral, and a charging capacitance of each phase of the electrical power system based on the line voltage of each phase, the line-to-neutral voltage of each phase, a frequency of the electrical power system, and the value of the neutral resistor, a phase charging current for each phase of the electrical power system based on the charging capacitance of each phase, the line voltage of each phase, and the frequency of the electrical power system, and the system charging current based on the phase charging current for each phase.

In still another embodiment, an apparatus for determining a system charging current in an electrical power system having three phases, a plurality of feeders, a feeder current sensor for each of the plurality of feeders, a ground, a neutral, and a neutral resistor electrically coupling the neutral to the ground, wherein one phase of the electrical power system has a fault to the ground such that the fault is not in disposed any of the plurality of feeders comprises an input module and a processor, wherein: the input module is configured to be electrically coupled to the feeder current sensor for each of the plurality of feeders such that the input module measures a net feeder current for each of the plurality of feeders; the input module is electrically coupled to the processor such that the processor reads the net feeder current for each of the plurality of feeders; and the processor determines the system charging current based on the net feeder current for each of the plurality of feeders.

In yet another embodiment, an apparatus for determining a system charging current in an electrical power system having three phases, a plurality of feeders, a feeder current sensor for each of the plurality of feeders, a ground, a neutral, and a neutral resistor electrically coupling the neutral to the ground, wherein one phase of one of the plurality of feeders has a fault to the ground comprises an input module and a processor, wherein: the input module is configured to be electrically coupled to the feeder current sensor for each of the plurality of feeders and to the neutral or a neutral current sensor; the input module measures a net feeder current for each of the plurality of feeders based on the feeder current sensor for each of the plurality of feeders; the input module measures a neutral voltage or a neutral current based on the neutral current sensor; the input module is electrically coupled to the processor such that the processor reads the net feeder current for each of the plurality of feeders and the neutral voltage or the neutral current; the processor determines the neutral current in the neutral resistor either based on the neutral current measured by the input module or based on the neutral voltage and a value of the neutral resistor; and the processor determines the system charging current based on the net feeder current for each of the plurality of feeders and the neutral current.

### BRIEF DESCRIPTION OF THE DRAWINGS

The embodiments set forth in the drawings are illustrative and exemplary in nature and not intended to limit the inventions defined by the claims. The following detailed description of the illustrative embodiments can be understood when read in conjunction with the following drawings, where like structure is indicated with like reference designators (numeric, alphabetic, and alphanumeric) and in which:

FIG. 1 depicts a schematic of an electrical power system according to one or more embodiments shown and described herein;

FIG. 2 depicts a schematic of an electrical power system having a plurality of feeders according to one or more embodiments shown and described herein;

FIG. 3 depicts a graph of an inverse time delay for recognizing a fault condition based on the neutral current according to one or more embodiments shown and described herein;

FIG. 4 depicts a graph of feeder currents and a neutral current according to one or more embodiments shown and described herein;

FIG. 5 depicts a schematic of an apparatus for detecting a fault in an electrical power system according to one or more embodiments shown and described herein; and

FIG. 6 depicts a fault output signal according to one or more embodiments shown and described herein.

### DETAILED DESCRIPTION

The embodiments described herein generally relate to methods and apparatuses for measuring charging current in an electrical power system having three phases. The electrical power system may also have a plurality of feeders. The embodiments described herein may also be able to determine whether a fault had occurred in the system and to distinguish between actual faults and charging currents (which may always be present in the system).

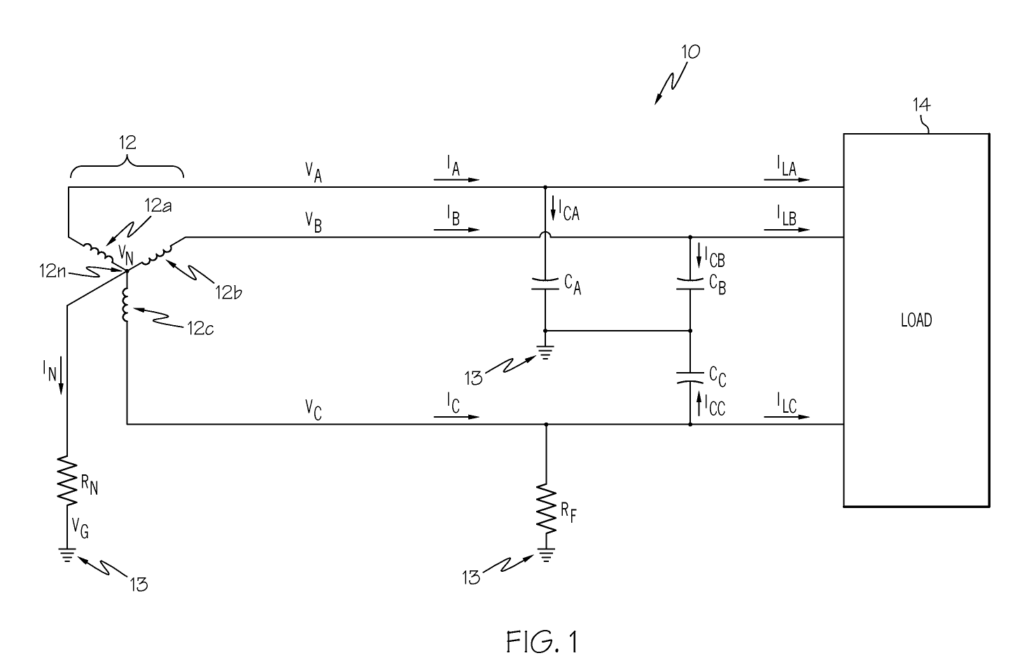

FIG. 1 depicts an electrical power system 10 having three phases represented by V_{A}, V_{B}, and V_{C}, wherein V_{A} may represent the voltage on phase “A,” V_{B} may represent the voltage on phase “B,” and V_{C} may represent the voltage on phase “C.” The voltage of the three phases may be 120° out of phase with respect to each other, such that one voltage may be considered as having a phase of 0°, another voltage may be considered as having a phase of 120°, and the other voltage may be considered as having a phase of 240°. The voltage on each phase may be approximately the same when the system 10 is operating normally and may be, for example, approximately 240 Volts AC (“VAC”), 480 VAC, or any other suitable voltage.

The three phases of the electrical power system 10 may be generated by the secondary 12 of a three-phase electrical transformer connected in a wye configuration, as shown in FIG. 1. The secondary 12 may have three windings 12a-c, one end of which may be connected together at a neutral 12n, which may have a neutral voltage V_{N}. The other end of the windings 12a-c may establish the phase voltages (V_{A}, V_{B}, V_{C}). The primary of the transformer (not shown) may be connected to a local power grid so as to supply electrical power to the secondary 12. Alternatively, the three phases of the electrical power system 10 may be generated by an electrical generator (not shown) having three windings functionally equivalent to the windings 12a-c of the transformer. Other ways of generating a three-phase electrical power system may be used as well, as is known in the art. The three phases of the electrical power system 10 may be electrically coupled to a load 14, which may consume electrical power.

The neutral 12n may be disposed at or near the secondary 12 of the transformer, such as where the windings 12a-c of the secondary 12 are connected together. The neutral 12n may be electrically coupled to the ground 13 through a neutral resistor R_{N}. The ground 13 may ultimately be coupled to earth ground and may be the ground for the system. In some systems, a metal rod may be driven into the earth in order to establish the earth ground. The neutral resistor R_{N} may be a power resistor capable of dissipating 50 Watts of power or more and may have a value of approximately 55 Ohms, for example. As such, the neutral resistor R_{N} may have water or forced-air cooling. It should be understood that any size or value of resistor may be utilized, depending on the particular application. Furthermore, more than one neutral resistor may be used either in series, in parallel, or in a combination thereof

The system 10 may have load 14 which may comprise, for example, motors, lights, heaters, machines, and other such devices. Normally the load 14 may consume power from the system 10, although some loads may be capable of temporarily generating power (e.g., regenerative braking of a motor). Although only one load 14 is shown, it is contemplated that the load 14 may comprise any number of devices. The load 14 may be resistive, inductive, or capacitive.

The electrical current in each phase may be represented by I_{A}, I_{B}, and I_{C}, as shown in FIG. 1. In this embodiment, the current in phase A is I_{A}, the current in phase B is I_{B}, and the current in phase C is I_{C}. Like the phase voltages V_{A}, V_{B}, and V_{C}, the phase currents I_{A}, I_{B}, and I_{C} may be 120° out of phase with respect to each other. The phase angle between a particular phase voltage and the corresponding phase current may generally range from −90° to +90°, depending on the type of load. When the phase angle between the phase voltage and phase current is 0°, they are considered “in phase.” As is known in the art, capacitive loads cause the current to lead the voltage, and inductive loads cause the current to lag the voltage. Many electrical systems are designed with loads that are neither capacitive nor inductive (i.e., purely resistive) so that the power factor (i.e., the ratio of real power to the apparent power) is as near to 1.0 as possible in order to maximize real power transfer.

The phase voltages V_{A}, V_{B}, and V_{C} are normally about equal. However, they could vary, either collectively or from one another, based on a number of factors. For example, the local power grid (which supplies power to the primary of the transformer) may have unbalanced phase voltages. Also, a load 14 may draw more current on one of the phases and cause that phase voltage to be lower than the others. This may be due to, for example, IR losses (current times resistance) in the secondary 12 of the transformer or the wiring leading to the load 14.

Furthermore, the system 10 may have a charging capacitance, shown as C_{A}, C_{B}, and C_{C}, for each phase. This charging capacitance may be inherent in the system 10 and may be caused by a number of factors, including but not limited to the stray capacitance introduced, for example, by the wiring, surge arrestors, the load 14, or other components in the system. The charging capacitance C_{A}, C_{B}, and C_{C} is electrically shown as “lumped” capacitors between each phase and the ground: C_{A} for phase A, C_{B} for phase B, and C_{C} for phase C. It is to be understood that the charging capacitance may embody the distributed capacitance of the system including phase-to-phase capacitance. The charging capacitance C_{A}, C_{B}, and C_{C} for each phase may be approximately equal, in which case the phase charging current caused by the charging capacitance is also approximately equal. However, if the charging capacitance C_{A}, C_{B}, and C_{C} is different for one or more of the phases, then the corresponding phase charging current may also be different for each phase. In this case, the phase charging currents may be unbalanced.

The system charging current I_{CS} may be the vector sum of the three phase charging currents. When the charging capacitance for each phase is approximately the same, the system charging current I_{CS} may be approximately zero (since the vector sum of the individual phase charging currents is approximately zero). Likewise, when the charging capacitance for each phase is different, the system charging current I_{CS} may be non-zero. Because the phase charging currents are capacitive in nature, they may lead the phase voltage by about 90°. The system charging current I_{CS} may be relatively small when compared to the amount of current delivered to the load 14. However, the system charging current I_{CS} may always be present since the charging capacitance is inherent in the system, while the current delivered to the load can vary substantially, depending on whether the load is demanding power. Because the phase current I_{A}, I_{B}, and i_{C} may be a sum of the phase charging current and the phase load current, the phase current may either lead, lag, or be in phase with the phase voltage, depending on the phase charging current, the electrical characteristics of the load, and how much power is demanded by the load at any given instant in time.

The system charging current I_{CS} can change over time due to, for example, aging of the components of the system 10, variations in the phase voltages, or changes to the wiring or load of the system 10. Regarding aging, insulation on components such as the wiring (e.g., the insulation on the wiring) may crack or shrink over time causing a change in the charging capacitance. The variations in the phase voltages may be caused by imperfections in the local electrical grid. And the changes to the system 10 may include adding, removing, or changing components such as the wiring, circuit breakers, or the loads. As a result, the system charging current I_{CS} may vary over time.

When the system 10 is balanced (i.e., the phase voltages, the phase charging capacitance, and phase load current are approximately equal), the voltage at the neutral 12n may be approximately zero volts with respect to the ground (i.e., measured from the neutral 12n to the ground). As a result, the neutral current I_{N} is also approximately zero due to Ohm's Law. However, as the system 10 becomes unbalanced, the neutral current I_{N} may increase. The system 10 may become unbalanced if the phase voltages are not equal, the phase load currents are not equal, the phase charging capacitors are not equal, or any combination thereof

Furthermore, the system 10 may develop a fault from time to time. The fault may be a phase-to-ground fault or a phase-to-phase fault. A phase-to-ground fault may be an unexpected current path from one of the phases to the ground (e.g., R_{F} in FIG. 1). A phase-to-phase fault may be an unexpected current path between two of the phases. The “unexpected current path” may be resistive, capacitive, and/or inductive and may also include a short circuit. The fault may occur on any part of the system 10, including but not limited to the secondary 12 of the transformer, the wiring, and the load 14. As an example of a phase-to-phase fault, if the load 14 is an electrical motor, a fault may develop in the motor between two phases due to aging and corresponding breakdown of the electrical insulation between motor windings. As an example of a phase-to-ground fault, a phase of the system 10 (or a wire coupled to a phase of the system) may be inadvertently damaged, causing one of the phases to be shorted to the ground. Many other types of faults may occur, and two or more faults may occur at the same time.

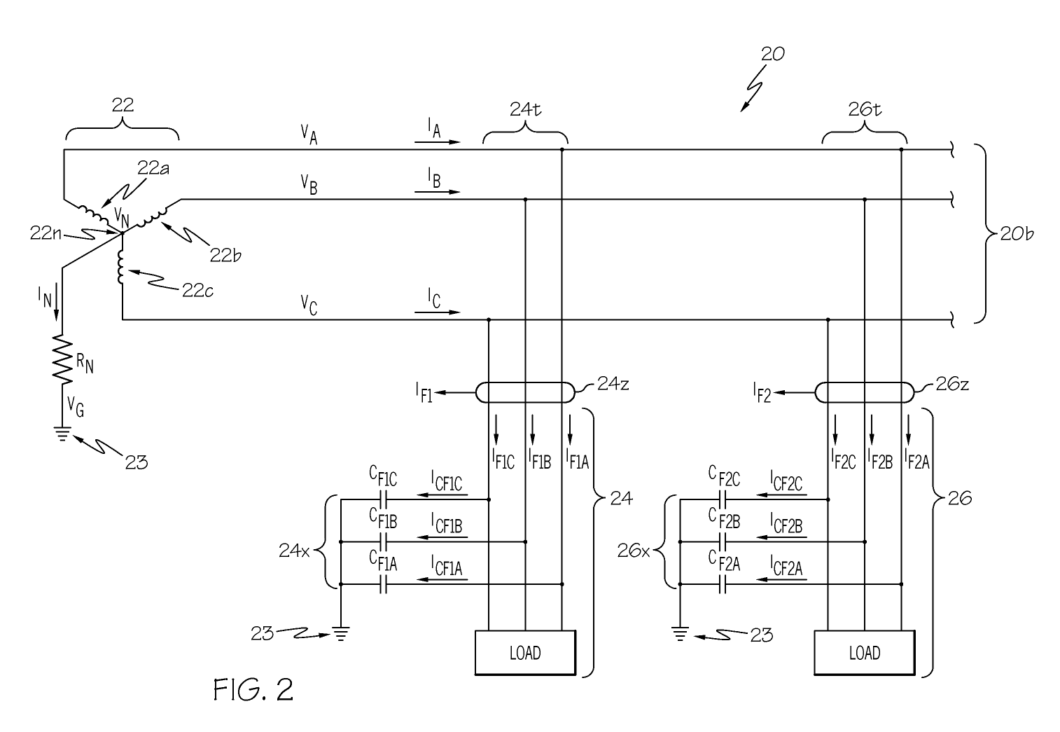

FIG. 2 depicts another embodiment of an electrical power system 20 having three phases (V_{A}, V_{B}, and V_{C}); a plurality of feeders 24, 26; a feeder current sensor 24z, 26z for each of the plurality of feeders 24, 26; a ground V_{G}; a neutral V_{N}; and a neutral resistor R_{N} electrically coupling the neutral to the ground. The electrical power system 20 of FIG. 2 may generally operate as the electrical power system described in FIG. 1. As such, the electrical power system 20 of FIG. 2 may comprise a secondary 22 of a transformer, which may include three windings 22a-c, one for each phase. The electrical power system 20 may also comprise a neutral 22n having a neutral voltage V_{N}, a ground 23, and a neutral resistor R_{N} which couples the neutral 22n to the ground 23. The system may also comprise a plurality of feeders 24, 26. Although two feeders 24, 26 are shown, any number of feeders is contemplated.

Each feeder 24, 26 may tap into the system bus 20b of the electrical power system 20. For example, feeder 24 may tap into the system bus 20b at location 24t, and feeder 26 may tap into the system bus 20b at location 26t. Each feeder may have a load 24y, 26y, which may include any number of devices, including but not limited to motors, lights, machinery, and so forth. Each feeder may be used for a particular machine or may be used to supply electricity to a portion of a building or factory.

Each feeder 24, 26 may also have a feeder current sensor 24z, 26z which is capable of sensing the net feeder current for each feeder, wherein the “net feeder current” is defined as the vector sum of the individual phase currents for a particular feeder. As an example, feeder current sensor 24z may be capable of sensing the vector sum of I_{F1A} (the “A” phase current for feeder 24), I_{HB} (the “B” phase current for feeder 24), and I_{F1C} (the “C” phase current for feeder 24). The output of the feeder current sensor 24z, 26z may be the vector sum of the individual phase currents for each feeder: I_{H} is the net feeder current for feeder 24, and I_{F2} is the net feeder current for feeder 26. Because the net feeder current is the vector sum of the individual phase currents for that feeder, the net feeder current may correspond to the ground current for that particular feeder.

As discussed above with reference to the electrical power system of FIG. 1, each feeder 24, 26 of FIG. 2 may have charging capacitance on each phase, which may be represented by lumped capacitors as shown in FIG. 2. For example, with respect to feeder 24, C_{F1A} may be the charging capacitor for the “A” phase; C_{HB} may be the charging capacitor for the “B” phase; and C_{F1C} may be the charging capacitor for the “C” phase. Feeder 26 has similar charging capacitors. Likewise, there may be stray capacitance on the wires of the system bus 20b, but this may contribute a negligible amount to the system charging current I_{CS}. Thus, the system charging current I_{CS} of the electrical power system 20 may be determined by summing the net feeder current for each feeder 24, 26 including the system bus 20b. As an example, the system charging current I_{CS} may simply be the vector sum of the net feeder current for each feeder. Other ways of determining the system charging I_{CS} current, based on the net feeder currents, may be used as well.

Referring to FIGS. 1 and 2, the neutral current I_{N} may indicate whether the system 10 is balanced: it may be approximately zero when balanced, and may increase as the system 10 becomes unbalanced. Generally, the higher the value of the neutral current I_{N}, the more unbalanced the system 10 may be. When a fault occurs, the neutral current I_{N} may increase due to the propensity of such faults to cause the system 10 to become unbalanced. The amount of increase in the neutral current I_{N} depends on the type of fault. Some faults may cause I_{N} to increase gradually over time. Other faults may cause I_{N} to increase very rapidly. Still other faults (or multiple faults) may not cause I_{N} to change at all. One way to determine whether a fault exists is by simply observing the instantaneous value of the neutral current I_{N}. If I_{N} exceeds a predetermined neutral current threshold I_{NT}, a fault may exist in the system. However, this type of methodology may not be able to distinguish between increases in the neutral current I_{N}, which are due to an increase in the system charging current I_{CS}, and increases in the neutral current I_{N}, which are due to actual faults in the system. Thus, methods and apparatuses are needed that are capable of measuring I_{N} and distinguishing between increases in the system charging current I_{CS} and actual faults. In particular, methods and apparatuses are needed which can recognize changes in the system charging current I_{CS} so that increases in the neutral current I_{N} can be distinguished from faults. Such methods may help prevent false alarms. FIG. 4 depicts a graphs of the neutral current I_{N} and the neutral current threshold I_{NT}. At time t₁, the neutral current I_{N} begins to increase and subsequently exceeds the neutral current threshold I_{NT}, upon which a fault may be recognized. At time t₂, the neutral current I_{N} begins to decrease and subsequently falls below the neutral current threshold I_{NT}, upon which a fault may no longer be recognized.

For the purposes of this disclosure, “line voltage” is defined as the voltage of a phase of the electrical power system measured with respect to the ground. The line voltages for each phase may be represented by V_{AG}, V_{BG}, and V_{CG}, respectively. For the purposes of this disclosure, “line-to-neutral voltage” is defined as the voltage of a phase of the electrical power system measured with respect to the neutral. The line-to-neutral voltages for each phase may be represented by V_{AN}, V_{BN}, and V_{CN}, respectively. For the purposes of this disclosure, “neutral voltage” is defined as the voltage of the neutral measured with respect to the ground and may be represented by V_{N}. The neutral voltage may also be determined by multiplying the neutral current I_{N} by the value of the neutral resistor R_{N} (i.e., Ohm's Law). For the purposes of this disclosure, using the term “measure” or “determine,” in any grammatical form, with respect to voltage or electrical current means that the amplitude and/or phase (i.e., angular phase) may be measured, determined, or calculated in any suitable way. For example, measuring the line voltage may mean measuring the amplitude of the voltage and/or phase of the voltage. As another example, determining a current may mean calculating the amplitude of the current and/or phase of the current. With respect to other electrical characteristics (e.g., measuring the value of a resistor or a capacitor), measuring or determining may refer to the scalar value of the item.

Referring to FIGS. 1 and 2, a method of one embodiment is disclosed for determining the system charging current in an electrical power system 10 having three phases (V_{A}, V_{B}, V_{C}), a ground 13, a neutral 12n, and a neutral resistor R_{N} electrically coupling the neutral 12n to the ground 13. The electrical system may have no feeders (e.g., FIG. 1) or it may have feeders (e.g., FIG. 2). The method may comprise a number of acts, which may be performed in any suitable order. One act of the method may measure the line voltage (V_{AG}, V_{BG}, WO of each phase of the electrical power system. Another act of the method may determine a line-to-neutral voltage (V_{AN}, V_{BN}, V_{CN}) of each phase of the electrical power system. The line voltages may be measured in any suitable fashion, such as using an analog or digital voltmeter, a data acquisition system, or a dedicated apparatus. The line-to-neutral voltages may be measured directly (like the line voltages) or may be determined by, for example, taking the line voltage plus the neutral voltage. Because of the known phase angle relationship between each phase of the electrical power system, it may be sufficient to only measure the voltage amplitude.

Another act of the method may determine a charging capacitance (C_{A}, C_{B}, C_{C}) of each phase of the electrical power system based on the line voltage of each phase (V_{AG}, V_{BG}, V_{CG}), the line-to-neutral voltage of each phase (V_{AN}, V_{BN}, V_{CN}), a frequency of the electrical power system, and a value of the neutral resistor R_{N}. Another act may determine a phase charging current (I_{CA}, I_{CB}, and I_{CC}) for each phase of the electrical power system based on the charging capacitance of each phase (C_{A}, C_{B}, C_{C}), the line voltage of each phase (V_{AG}, V_{BG}, V_{CG}), and the frequency of the electrical power system. Finally, an act of the method may determine the system charging current I_{CS} based on the phase charging current (I_{CA}, I_{CB}, and I_{CC}) for each phase. The acts which comprise the method may be performed in any suitable order.

Determine a charging capacitance of each phase (C_{A}, C_{B}, and C_{C}) may be based on the line voltage (V_{AG}, V_{BG}, and V_{CG}), the line-to-neutral voltage (V_{AN}, V_{BN}, and V_{CN}), the frequency of the electrical power system, and the value of the neutral resistor R_{N}. This may be accomplished by solving the following three equations:

$$\begin{matrix}{V}_{AG } = {V}_{AN} - \frac{jω ( {C}_{A} {V}_{AN} + {C}_{B} {V}_{BN} + {C}_{C} {V}_{CN} )}{j ω ( {C}_{A} + {C}_{B} + {C}_{C} ) + 1 / {R}_{N}} , & ( Eq . 1 ) \\ {V}_{BG} = {V}_{BN} - \frac{j ω ( {C}_{A} {V}_{AN} + {C}_{B} {V}_{BN} + {C}_{C} {V}_{CN } )}{j ω ( {C}_{A} + {C}_{B} + {C}_{C} ) + 1 / {R}_{N}} , \\ and & ( Eq . 2 ) \\ {V}_{CG} = {V}_{CN} - \frac{j ω ( {C}_{A} {V}_{AN} + {C}_{B} {V}_{BN} + {C}_{C} {V}_{CN} )}{j ω ( {C}_{A} + {C}_{B} + {C}_{C} ) + 1 / {R}_{N}} . & ( Eq . 3 )\end{matrix}$$

In these equations, all variables may be known except for charging capacitance (C_{A}, C_{B}, C_{C}) for each phase. Thus, these equations may be solved since there are three independent equations and three unknowns. Conventional mathematical algorithms may be used to solve for C_{A}, C_{B}, and C_{C}, and these algorithms may be adapted to be performed by a processor or computer. As previously discussed herein, line voltage for each may be represented by V_{AG}, V_{BG}, and V_{CG}; and the line-to-neutral voltage may be represented by V_{AN}, V_{BN}, and V_{CN}. Furthermore, j=\sqrt{−1}, R_{N} is the value of the neutral resistor, and ω=2πf, where f is the frequency of the electrical power system. The frequency of the electrical power system f may be, for example, 60 Hertz in the United States and 50 Hertz in Europe.

After determining the charging capacitance for each phase (C_{A}, C_{B}, and C_{C}), the phase charging current (I_{CA}, I_{CB}, and I_{CC}) for each phase may be calculated by solving the following equations:

I_{CA}=V_{AG}×jωC_{A} (Eq. 4),

I_{CB}=V_{BG}×jωC_{B} (Eq. 5), and

I_{CC}=V_{CG}×jωDC_{C} (Eq. 6),

where, j=\sqrt{−1} and ω=2πf, where f is the frequency of the electrical power system. The solution to these equations may produce complex numbers (i.e., numbers having an amplitude and phase angle). The system charging current may simply be the vector sum of the phase charging currents: I_{CS}=I_{CA}+I_{CB}+I_{CC}.

Other embodiments of the methods disclosed herein may be operable to determine whether a fault exists in the electrical power system. Acts of this method may include determining a neutral current threshold I_{NT} based on the system charging current I_{CS}, measuring or determining a neutral current I_{N} in the neutral resistor, and setting a state of a fault output signal based on whether the neutral current I_{N} exceeds the neutral current threshold I_{NT}. States of the fault output signal may include “FAULT” (thus indicating a fault in the system) and “NO FAULT” (thus indication no fault in the system). There are numerous ways in which to determine the neutral current threshold I_{NT} based on the system charging current I_{CS}. For example, the neutral current threshold I_{NT} may be determined to some fixed multiple of the system charging current I_{CS} which is greater than 1, such as 1.5. Any other suitable multiplier may be used as well. Because the neutral current threshold I_{NT} may be based on the system charging current I_{CS}, the neutral current threshold I_{NT} may vary as the system charging current varies (e.g., such as when changes are made to the electrical power system). Thus, neutral current threshold I_{NT} may be adaptable to changing conditions of the electrical power system and, as such, may help reduce false alarms.

As another example, the neutral current threshold I_{NT} may be based on an average of the system charging current I_{CS}, which may be averaged over some averaging time period, such as two weeks or one month, for example. This average charging current may be a “running average” which takes the most-recent samples of I_{CS} (averaged over the averaging time period). For example, the neutral current threshold I_{NT} may be set to 1.5 times the average of the system charging current I_{CS}, which is averaged over the averaging time period. As another example, the neutral current threshold I_{NT} may be determined to be 1.5 times the peak average of the system charging current I_{CS}, which is averaged over the averaging time period. The peak may be the highest average I_{CS} which occurred during the previous averaging time period. Many other methods to determine the neutral current threshold I_{NT} may be used as well, including those which are based on the system charging current I_{CS} or the phase charging currents (I_{CA}, I_{CB}, I_{CC}) for each phase.

The neutral current I_{N} may be measured by electrically coupling a neutral current sensor to the neutral resistor R_{N} and measuring the current directly from the sensor. One example of a current sensor is a current transformer (CT) which may be inserted in series with the neutral resistor R_{N}. Alternatively, the neutral current I_{N} may be measured indirectly by measuring the neutral voltage V_{N} (with respect to the ground) and dividing by the value of the neutral resistor: I_{N}=V_{N}/R_{N}. Other ways of measuring the neutral current I_{N} may be used as well.

In yet another embodiment, the state of the fault output signal may be based on whether the neutral current I_{N} instantaneously exceeds the neutral current threshold I_{NT}. That is, if the neutral current I_{N} exceeds the neutral current threshold I_{NT} for any amount of time, a fault condition may be recognized (and the fault output signal may be set accordingly). However, the state of the fault output signal may also be based on a time delay function, which may operate in at least two different modes. In the first mode, a predetermined time period may provide a time delay before setting the state of the fault output signal to FAULT. This may operate as follows. When the neutral current I_{N} exceeds the neutral current threshold I_{NT}, a timer may be started which begins at zero and counts up to the predetermined time period. While the timer is counting up, the output state may remain in a NO FAULT state. If the neutral current I_{N} continuously exceeds the neutral current threshold I_{NT}, the timer may continue to run, and the fault output signal may be set to a FAULT state when the timer reaches the predetermined time period. Otherwise, if I_{N} ever falls below I_{NT} before the timer has reached the predetermined time period, the timer may be reset to zero (such that the timer begins counting up from zero if I_{N} exceeds I_{NT} again). In short, this mode may require that I_{N} continuously exceed I_{NT} for the predetermined time period in order for the fault output signal to be set to FAULT. The predetermined time period may be, for example 1 second, 10 seconds, 1 minute, or any other suitable time period.

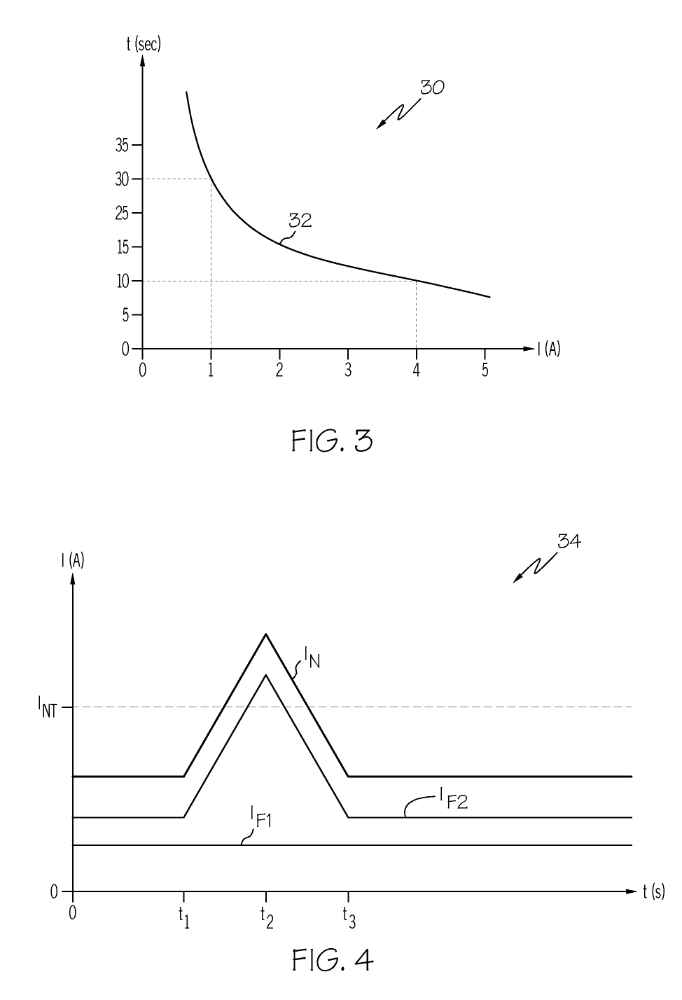

The second mode may operate substantially the same as the first mode, except that the predetermined time period is replaced by an inverse time delay (e.g., an adaptable time period), which is graphically illustrated in FIG. 3. The adaptable time period may be based on how much I_{N} exceeds I_{NT}. For example, if I_{N} exceeds I_{NT} by 1 Amp, the adaptable time period may be set to 30 seconds; if I_{N} exceeds I_{NT} by 4 Amps, the adaptable time period may be set to 10 seconds. Thus, as with the predetermined time period, I_{N} must continuously exceed I_{NT} for the adaptable time period in order for the fault output signal to be set to FAULT. In cases where the amount of current by which I_{N} exceeds I_{NT} varies, the act may either continue to use the original adaptable time period, or it may continuously change the adaptable time period. Other techniques for changing the adaptable time period may be used as well.

As discussed herein, the fault output signal may be set to a FAULT state and a NO FAULT state. Once set to a FAULT state, the output signal may remain in that state (i.e., may be “sticky”) until it is reset to the NO FAULT state by, for example, an operator. Alternatively, the fault output signal may be simply based on whether the neutral current I_{N} exceeds the neutral current threshold I_{NT}, including based on the time delay function. In addition to the fault output signal, a warning output signal may also be provided which could provide an advanced warning that the neutral current I_{N} is approaching the neutral current threshold I_{NT}. For example, a warning output signal may be set based on whether the neutral current I_{N} exceeds a neutral current warning threshold, which may be lower than the neutral current threshold I_{NT}. This may provide an operator with an advanced warning that a fault is developing in the electrical power system and may provide the operator with the opportunity to investigate and possibly correct the problem before it becomes a full-blown fault. The warning output signal may be based on the neutral current I_{N} and a neutral current warning threshold I_{NW}, which may be established in any manner described herein like the neutral current threshold I_{NT}. Other of similar types of warning and/or alarm signals may be generated as well and may be based on the neutral current I_{N} and the system charging current I_{CS}.

The fault output signal (or any of other output signals) may comprise a mechanical relay, a solid-state relay, or any suitable electrical signal. If a relay is used (either mechanical or solid-state), the relay may be open to indicate one state, and it may be closed to indicate the other state. For example, the relay may be closed in the NO FAULT state, and it may be open in the FAULT state. This may facilitate a “fail safe” system in which FAULT state is recognized either when the relay indicates this state or when a wire is broken. Other types of fault output signals may be used as well, including, but not limited, to radio frequency (RF) signals, optical signals, and signals represented by data being transmitted in a serial data transmission system, such as Ethernet.

The system charging current I_{CS} may also be used to adjust the value of the neutral resistor R_{N}. Accordingly, the neutral resistor R_{N} may comprise a series of discrete resistors or a variable resistor which may permit its resistance value to be adjusted. For example, a neutral resistor adjustment signal may be electrically coupled to the neutral resistor R_{N} such that the neutral resistor adjustment signal adjusts the value of the neutral resistor R_{N}. In this fashion, the value of the neutral resistor R_{N} may be based on the value of the system charging current I_{CS}.

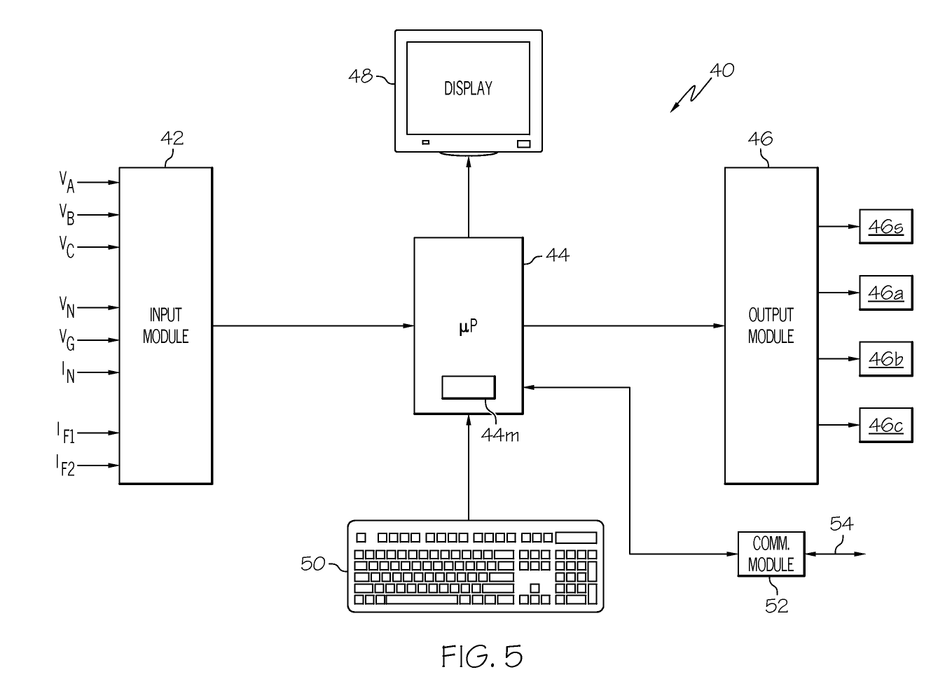

Referring now to FIG. 5, an apparatus 40 is shown for determining a system charging current I_{CS} in an electrical power system (not shown) having three phases, a ground, a neutral, and a neutral resistor electrically coupling the neutral to the ground. The apparatus 40 may comprise an input module 42, a processor 44, an output module 46, a display 48, an entry device 50, and a communication module 52. It is to be understood that the apparatus 40 may comprise other elements (which are not shown in FIG. 5) such as, but not limited to, a power supply, a housing, and so forth.

The input module 42 may be configured to be electrically coupled to each phase (V_{A}, V_{B}, V_{C}) of the electrical power system, the ground V_{G}, and the neutral V_{N}. For electrical power systems with feeders, the input module 42 may also be configured to be electrically coupled to the feeder current sensor 24z, 26z for each feeder. If a neutral current sensor is used for the neutral current, the input module 42 may be configured to measure the neutral current I_{N} directly from this input. If a neutral current sensor is not used, the processor 44 may be configured to determine the neutral current I_{N} indirectly by taking the neutral voltage V_{N} divided by the value of the neutral resistor (I_{N}=V_{N}/R_{N}). The electrical coupling of the inputs may be done, for example, via an electrical connector (not shown), such as a terminal block or a plug-style connector. The electrical coupling of the inputs to the input module 42 may be done via wires, cables, or other suitable devices. The input module 42 may: measure a line voltage (V_{AG}, V_{BG}, V_{CG}) of each phase of the electrical power system and measure a neutral voltage V_{N} or a neutral current I_{N} based on the neutral current sensor. In electrical power systems with feeders, the input module may also measure the net feeder current (I_{H}, I_{F2}) for each feeder. Because the apparatus 40 may operate as a discrete-time system, the input module 42 may periodically measure the voltage and current inputs at a fixed update rate, such as every 1 millisecond, for example. Other updates rates may be used as well.

The input module 42 may use any suitable device or circuit to measure voltage and current including, for example, resister divider networks, transformers, analog-to-digital converters, and so forth. For example, the input module 42 may use a transformer to measure the voltage inputs (V_{AG}, V_{BG}, V_{CG}, V_{AN}, V_{BN}, V_{CN}, and V_{N}), some of which may have a relatively high voltage, such as 480 VAC. As another example, the input module 42 may use a resistor divider to measure the current inputs (I_{N}, I_{F1}, I_{F2}), which may be sensed by a current transformer. The input module 42 may comprise other electrical components in order to measure the inputs and convert them into a signal (or signals) which can be read by the processor 44. For example, the input module 42 may use operational amplifiers, analog-to-digital converters, and other such elements in order to perform these conversions. The input module 42 may be electrically coupled to the processor 44 such that the processor 44 is able to read the value of the voltages and currents provided by the input module 42. As such, the input module 42 may convert the voltage and current inputs into a suitable analog or digital signal (or signals) which can be read by the processor 44. For example, the input module 42 may convert the neutral voltage V_{N} into a digital signal that can be read by the processor 44. The digital signal may comprise a serial bus such as Serial Peripheral Interface (SPI) bus or other suitable protocol.

The processor 44 may be an 8-bit processor, a 16-bit processor, or any other suitable device capable of performing the methods described herein. The processor 44 may comprise a memory 44m, which may be used to store the computer program or other data. The processor 44 may also include other devices such as timers, interrupt controllers, serial interface modules, etc. in order to facilitate its operation in the apparatus 40. The processor 44 may execute a computer program (which may be stored in the memory 44m) which embody instructions capable of carrying out the methods described herein.

The processor 44 may determine the neutral current I_{N} by taking the neutral voltage V_{N} and dividing by the value of the neutral resistor R_{N} (i.e., by using Ohm's Law) or by reading the neutral current I_{N} directly from the input module 42 via the neutral current sensor. The value of the neutral resistor R_{N} may be entered into the apparatus 40 (and read by the processor 44) by an operator entering this value via the entry device 50, as described herein. The neutral current sensor may comprise a current transformer (not shown) electrically coupled to the neutral resistor R_{N} and configured to measure the neutral current I_{N}. In this case, the processor 44 may read the neutral current I_{N} directly from the input module 42. Other methods of determining the neutral current I_{N} may be used as well.

The output module 46 may comprise a system fault output signal 46s and one or more feeder fault output signals 46a-c and may be electrically coupled to the processor 44 such that the processor 44 may set a state the fault output signals 46s, 46a-c based on the neutral current I_{N}, the neutral current threshold I_{NT}, and/or the net feeder current (I_{F1}, I_{F2}). The fault output signals 46a-c, 46s may comprise a mechanical relay, a solid-state relay, or any suitable electrical signal. For example, each may comprise a solid-state relay capable of opening and closing so as to indicate the state of the fault output signal 46a-c, 46s. A closed state may indicate a FAULT, while an open state may indicate NO FAULT. There may be a system fault output signal 46s, as well as one or more feeder fault output signals 46a-c, one for each feeder.

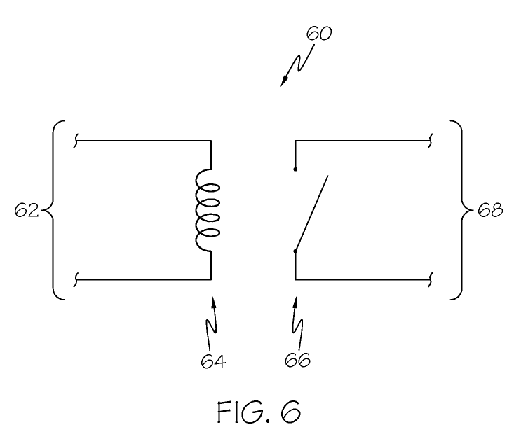

FIG. 6 depicts one embodiment of a relay 60 capable of producing an output signal 68. The relay 60 may comprise a coil 64 and a contact 66. The coil 64 may be electrically coupled to the processor (not shown) via leads 62. The contact 66 may generate the output signal 68, which may comprise two wires. The processor may apply electrical current to the coil 64 in order to open and close the contact 66, as is known in the art. The relay 60 may be a normally-opened relay or a normally-closed relay. Accordingly, the processor may set a state of the output signal 68 by applying or not applying an electrical current to the coil 64. The output signal 68 may be electrically coupled to an external device (not shown) which is capable of reading the output signal 68 so as to ascertain its state. In this fashion, the processor may be able to set the state of the output signal 68 so as to indicate to the external device whether or not a fault exists. The relay may be a mechanical relay (as shown in FIG. 6), or it may be a solid-state relay which may use solid-state devices (e.g., transistors) to perform the function of the contact 66. Other types and forms of relays may be used as well.

Referring to FIG. 5 again, the display 48 may be electrically coupled to the processor 44 such that the processor 44 can write data to the display 48 which is to be shown on the display 48. The display 48 may display information about the electrical power system to which the apparatus 40 is coupled. As an example, the display 48 may indicate whether or not a system fault or a feeder fault is present. The display 48 may also indicate the various operating characteristics of the system such as, but not limited to, the value of the phase voltages, the value of the neutral current I_{N}, or the value of the net feeder currents. Other information may be displayed as well. The display 48 may be a liquid crystal display (LCD) or any suitable technology.

The apparatus 40 may further comprise an entry device 50 which may allow an operator of the apparatus 40 to enter information into the apparatus 40. The entry device 50 may be a typical keyboard, a mouse, a touch screen (e.g., coupled to the display 48), or any other suitable device. By using the entry device 50, the operator may set one or more operating characteristics of the apparatus 40, such as setting the predetermined time period for the neutral current threshold, setting the number of feeders in the electrical power system, or entering the value of the neutral resistor R_{N}, for example. Other parameters may be entered as well, such as the neutral current threshold (if using a fixed value), warning thresholds, etc. It is contemplated that the entry device 50 may be used to enter any information that may be useful for the operation of the apparatus 40.

Referring still to FIG. 5, the communication module 52 may allow the apparatus 40 to communicate information to and receive information from a second apparatus (not shown). The second apparatus may comprise many types of devices, including but not limited to a device similar to apparatus 40, a programmable logic controller, a personal computer, or a server. The communication module 52 may be electrically coupled to the processor 44 and the second apparatus such that the processor 44 and the second apparatus may exchange information with each other. The type of information exchanged may include operating characteristics of the electrical power system to which the apparatus 40 is coupled. For example, the apparatus 40 may transmit to the second apparatus information about voltages (e.g., V_{AN}, V_{BN}, V_{CN}, V_{AG}, V_{BG}, V_{CG}, and V_{N}) and currents (e.g., I_{CS}, I_{F1}, I_{F2}, and I_{N}) in the electrical power system. This may occur if the second apparatus is “data logging.” Other information available to the processor 44 may be transmitted as well (e.g., whether a fault has been detected). Similarly, the apparatus 40 may receive information from the second apparatus which may relate to information about a second electrical power system to which the second apparatus is coupled. In short, the apparatus 40 may transmit or receive many different types of information via the communication module 52.

The communication module 52 may communicate to the second apparatus via a wired or a wireless connection. For a wired connection, the communication module 52 may use Ethernet or any other current or yet-to-be-developed technology. For a wireless connection, the communication module 52 may use an optical technology, such as infrared light, or radio frequency (RF) technology, such as Bluetooth or Zigbee, for example. It is contemplated that the communication module 52 may employ any number of communication technologies and protocols.

The apparatus 40 may be electrically coupled to an electrical power system with or without feeders and may be capable of performing any of the methods described herein, such as the methods for determining the system charging current of the electrical power system and the methods for detecting a fault in an electrical power system. Such methods may be embodied in computer instructions of a computer program which may be executed by the processor 44. As previously discussed, the computer program may be stored in the memory 44m.

In one embodiment, the apparatus 40 may determine a system charging current in an electrical power system having three phases (V_{A}, V_{B}, V_{C}), a ground V_{G}, a neutral V_{N}, and a neutral resistor R_{N} electrically coupling the neutral to the ground. The electrical power system may have no feeders (as shown in FIG. 1) or it may have feeders (as shown in FIG. 2). The input module 42 may be configured to be electrically coupled to each phase of the electrical power system (V_{A}, V_{B}, V_{C}), the ground V_{G}, and the neutral V_{N} or a neutral current sensor. As such, the input module 42 may: measure a line voltage (V_{AG}, V_{BG}, V_{CG}) and measure a neutral voltage V_{N} or measure a neutral current I_{N} based on the neutral current sensor. The input module 42 could simultaneously measure both the neutral voltage V_{N} and neutral current I_{N}, if desired. The input module 42 may be electrically coupled to the processor 44 such that the processor 44 is operable to read these inputs (V_{AG}, V_{BG}, V_{CG}, and V_{N} or I_{N}) from the input module 42. The processor 44 may be operable to determine the neutral voltage V_{N} based on the measured neutral voltage V_{N} from the input module or based on the neutral current I_{N} and a value of the neutral resistor (i.e., V_{N}=I_{N}×R_{N}).

The processor may also: determine a line-to-neutral voltage (V_{AN}, V_{BN}, V_{CN}) of each phase of the electrical power system; determine a charging capacitance (C_{A}, C_{B}, C_{C}) of each phase of the electrical power system based on the line voltage (V_{AG}, V_{BG}, V_{CG}), the line-to-neutral voltage (V_{AN}, V_{BN}, V_{CN}), a frequency of the electrical power system, and a value of the neutral resistor R_{N}; determine a phase charging current (I_{CA}, I_{CB}, I_{CC}) for each phase based on the charging capacitance (C_{A}, C_{B}, C_{C}), the line voltage (V_{AG}, V_{BG}, V_{CG}), and the frequency of the electrical power system. Finally the apparatus 40 may determine the system charging current I_{CS} based on the phase charging current for each phase.

The processor 44 may also determine the charging capacitance (C_{A}, C_{B}, C_{C}) of each phase of the electrical power system by solving Eq. 1, Eq. 2, and Eq. 3 for C_{A}, C_{B}, and C_{C}, as described above. The processor 44 may be further operable to determine the phase charging current (I_{CA}, I_{CB}, I_{CC}) for each phase of the electrical power system by determining the phase charging current for the first phase by using Eq. 4, Eq. 5, and Eq. 6, as described above. Finally, the processor 44 may be operable to determine system charging current I_{CS} by taking the vector sum of the phase charging currents: I_{CS}=I_{CA}+I_{CB}+I_{CC}.

The processor 44 may further determine a neutral current I_{N} in the neutral resistor R_{N}, either by measuring the neutral current I_{N} directly from the input module 42 (via the neutral current sensor) or by dividing the neutral voltage V_{N} by the value of the neutral resistor R_{N}. The processor 44 may be operable to determine a neutral current threshold I_{NT} based on the system charging current I_{CS}. The neutral current threshold I_{NT} may be determined in any manner described herein. Finally, the processor 44 may be operable to set a state of the system fault output signal 46s based on whether the neutral current I_{N} exceeds the neutral current threshold I_{NT}.

As described herein, the processor 44 may set the neutral current threshold I_{NT} to be a multiple of the system charging current I_{CS} such as, for example, 1.5 times the sum of the phase charging currents. Alternatively, the processor 44 may set the state of the system fault output signal 46s based on whether the neutral current I_{N} exceeds the neutral current threshold I_{NT} for more than a predetermined time period, which may be a fixed number or may be based on by how much the neutral current I_{N} exceeds the neutral current threshold I_{NT} (see FIG. 3). The processor 44 may further set the neutral current threshold I_{NT} by determining a peak average value of a sum of the phase charging current for each phase, wherein the peak average value is measured over an averaging time period, such as two weeks or one month, for example.

The processor 44 may use the charging current I_{CS} to adjust the value of the neutral resistor R_{N}. The output module 46 may comprise a neutral resistor adjustment signal which may be set by the processor 44. The neutral resistor adjustment signal may embody the same characteristics as the fault output signal 46s, such as one or more relay outputs. Other types of signals may be used as well. The neutral resistor adjustment signal may be electrically coupled to the neutral resistor R_{N} such that processor 44 is operable to adjust the value of the neutral resistor R_{N}. In this fashion, the value of the neutral resistor R_{N} may be automatically adjusted by the apparatus 40 based on the value of the system charging current I_{CS}.

In another embodiment, the system charging current I_{CS} may also be determined by introducing a ground fault into the electrical power system. The system charging current may be determined as:

I_{CS}=\sqrt{I_{FT}²−I_{N}²},

where I_{FT} is the fault current (i.e., the current in the ground fault) and I_{N} is the neutral current. The apparatus 40 of FIG. 5 may be operable to automatically determine the system charging current I_{CS} in this manner. Introducing a ground fault (or any other fault) into the “electrical power system,” means that the fault is not introduced in any of the feeders 24, 26. That is, the fault is introduced before the feeder current sensor 24z, 26z (so that the fault current does not pass through the feeder current sensors). If the system has a plurality of feeders each having a feeder current sensor capable of measuring a net feeder current (I_{F1}, I_{F2}) for each feeder, the system charging current I_{CS} may also be a sum of the net feeder currents:

I_{CS}=ΣI_{F1}+I_{F2}+ . . . I_{FX},

where “X” is the number of feeders.

In another embodiment, the feeder charging currents (I_{CF1}, I_{CF2}) may also be determined by introducing a ground fault into one of the feeders of the electrical power system. The feeder having the ground fault may be determined by comparing the phase angle between the neutral current I_{N} and the net feeder current (I_{F1}, I_{F2}) for each of the plurality of feeders. The one net feeder current which is substantially in phase with the neutral current I_{N} may be the feeder having the fault. The other net feeder currents which substantially not in phase with the neutral current I_{N} likely do not have the fault. For the feeders which do not have the ground fault, the feeder charging current may simply comprise the net feeder current for that feeder as measured by the feeder current sensor. The system charging current I_{CS} may be determined based on the fault current and the feeder charging currents for the non-faulted feeders:

I_{CS}=\sqrt{I_{FX}²(FT)−I_{N}²},

where I_{CS} is the system charging current, I_{FX(FT)} is the net feeder current for the faulted feeder, and I_{N} is the neutral current.

For the feeder which has the ground fault, the feeder charging current may be:

I_{CFX}=I_{CS}−ΣI_{FX(NF)},

where I_{CFX} is the charging current for the feeder with the ground fault and ΣI_{FX(NF)} is a sum of the net feeder currents for the feeders which do not have the ground fault.

In another embodiment, the apparatus 40 may determine a system charging current I_{CS} in an electrical power system having three phases, a plurality of feeders, a feeder current sensor for each of the plurality of feeders, a ground, a neutral, and a neutral resistor electrically coupling the neutral to the ground. The processor 44 may be able to determine the system charging current I_{CS} by simply taking a vector sum of the net feeder current for each feeder. For example, I_{CS} may be determined by adding I_{F1} and I_{F2}.

The apparatus 40 of FIG. 3 may be operable to use any of the methods described herein for determining the system charging current in an electrical power system. For example, the apparatus 40 may operable to determine the system charging current by determining the phase charging currents, by measuring the net feeder currents, or by introducing a ground fault into the electrical power system, as described herein. The apparatus 40 may be operable to select a suitable method for determining the system charging current, based either manually (e.g., selected by a user) or automatically (e.g., having the processor select a method based on determining which inputs are electrically coupled to the apparatus 40). Thus, a single apparatus 40 may simultaneously embody all of the methods described herein to determine the system charging current I_{CS}.

It should now be understood that the methods and apparatuses described herein may be used to determine the system charging current I_{CS} and/or whether a system fault exists in an electrical power system. The methods and apparatuses may also be used to determine the system charging current in an electrical power system.

While particular embodiments and aspects of the present invention have been illustrated and described herein, various other changes and modifications may be made without departing from the spirit and scope of the invention. Moreover, although various inventive aspects have been described herein, such aspects need not be utilized in combination. It is therefore intended that the appended claims cover all such changes and modifications that are within the scope of this invention.

What is claimed is:

1. A method for determining a system charging current in an electrical power system having three phases, a ground, a neutral, and a neutral resistor electrically coupling the neutral to the ground, the method comprising:
measuring a line voltage of each phase of the electrical power system, wherein the line voltage is measured with respect to the ground;
measuring a line-to-neutral voltage of each phase of the electrical power system, wherein the line-to-neutral voltage is measured with respect to the neutral;
determining a charging capacitance of each phase of the electrical power system based on the line voltage of each phase, the line-to-neutral voltage of each phase, a frequency of the electrical power system, and a value of the neutral resistor;
determining a phase charging current for each phase of the electrical power system based on the charging capacitance of each phase, the line voltage of each phase, and the frequency of the electrical power system; and
determining the system charging current based on the phase charging current for each phase.

2. The method of claim 1, wherein determining the charging capacitance C_{A}, C_{B} , C_{C} of each phase of the electrical power system comprises solving the following equations for C_{A}, C_{B}, and
$${V}_{AG} = {V}_{AN} - \frac{j ω ( {C}_{A} {V}_{AN} + {C}_{B} {V}_{BN} + {C}_{C} {V}_{CN} )}{j ω ( {C}_{A} + {C}_{B} + {C}_{C} ) + 1 / {R}_{N}} , \\ {V}_{BG} = {V}_{BN} - \frac{j ω ( {C}_{A} {V}_{AN} + {C}_{B} {V}_{BN} + {C}_{C} {V}_{CN} )}{j ω ( {C}_{A} + {C}_{B} + {C}_{C} ) + 1 / {R}_{N}} , \\ and$$
$${V}_{CG} = {V}_{CN} - \frac{j ω ( {C}_{A} {V}_{AN} + {C}_{B} {V}_{BN} + {C}_{C} {V}_{CN} )}{j ω ( {C}_{A} + {C}_{B} + {C}_{C} ) + 1 / {R}_{N}} ,$$
wherein:
for a first phase of the electrical power system, V_{AG} is the line voltage, V_{A}, is the line-to-neutral voltage, and C_{A} is the charging capacitance;
for a second phase of the electrical power system, V_{BG} is the line voltage, V_{BN} is the line-to-neutral voltage, and C_{B} is the charging capacitance;
for a third phase of the electrical power system, V_{CG} is the line voltage, V_{CN} is the line-to-neutral voltage, and C_{C} is the charging capacitance;
j=\sqrt{−1};
R_{N} is the value of the neutral resistor; and
ω=2πf, where if is the frequency of the electrical power system.

3. The method of claim 2, wherein determining the phase charging current for each phase of the electrical power system comprises determining:
the phase charging current for the first phase I_{CA}=V_{AG}×jωC_{A};
the phase charging current for the second phase I_{CB}=V_{BG}×jωC_{B}; and
the phase charging current for the third phase I_{CC}=V_{CG}×jωC_{C}.

4. The method of claim 1, wherein determining the system charging current comprises taking a vector sum of the phase charging currents.

5. The method of claim 1, further comprising:
determining a neutral current threshold based on the system charging current;
determining a neutral current in the neutral resistor; and
setting a state of a fault output signal based whether the neutral current exceeds the neutral current threshold.

6. The method of claim 5, wherein determining the neutral current threshold comprises determining a peak average value of the system charging current, wherein the peak average value of the system charging current is determined over an averaging time period.

7. The method of claim 5, wherein determining the neutral current threshold comprises multiplying the system charging current by a number greater than 1.

8. The method of claim 5, wherein setting the state of the fault output signal is based on whether the neutral current exceeds the neutral current threshold for more than a predetermined time period.

9. The method of claim 8, wherein the predetermined time period is based on an amount of current by which the neutral current exceeds the neutral current threshold.

10. The method of claim 1, further comprising automatically adjusting the value of the neutral resistor based on the system charging current.

11. An apparatus for determining a system charging current in an electrical power system having three phases, a ground, a neutral, and a neutral resistor electrically coupling the neutral to the ground, the apparatus comprising an input module and a processor, wherein:
the input module is configured to be electrically coupled to each phase of the electrical power system, the ground, and the neutral or a neutral current sensor such that the input module:
measures a line voltage of each phase of the electrical power system, wherein the line voltage is measured with respect to the ground, and
measures a neutral voltage, wherein the neutral voltage is measured with respect to the ground, or measures a neutral current based on the neutral current sensor;
the input module is electrically coupled to the processor such that the processor reads the line voltage of each phase and the neutral voltage or the neutral current; and
the processor determines:
the neutral voltage based on the neutral voltage measured from the input module or based on the neutral current and a value of the neutral resistor;
a line-to-neutral voltage of each phase of the electrical power system, wherein the line-to-neutral voltage is measured with respect to the neutral, and
a charging capacitance of each phase of the electrical power system based on the line voltage of each phase, the line-to-neutral voltage of each phase, a frequency of the electrical power system, and the value of the neutral resistor,
a phase charging current for each phase of the electrical power system based on the charging capacitance of each phase, the line voltage of each phase, and the frequency of the electrical power system, and
the system charging current based on the phase charging current for each phase.

12. The apparatus of claim 11, wherein the processor determines the charging capacitance C_{A}, C_{B} , C_{C} of each phase of the electrical power system by solving the following equations for C_{A}, C_{B}, and C_{C}:
$${V}_{AG} = {V}_{AN} - \frac{jω ( {C}_{A} {V}_{AN} + {C}_{B} {V}_{BN} + {C}_{C} {V}_{CN} )}{j ω ( {C}_{A} + {C}_{B} + {C}_{C} ) + 1 / {R}_{N}} , \\ {V}_{BG} = {V}_{BN} - \frac{jω ( {C}_{A} {V}_{AN} + {C}_{B} {V}_{BN} + {C}_{C} {V}_{CN} )}{j ω ( {C}_{A} + {C}_{B} + {C}_{C} ) + 1 / {R}_{N}} , \\ and$$
$${V}_{CG} = {V}_{CN} - \frac{jω ( {C}_{A} {V}_{AN} + {C}_{B} {V}_{BN} + {C}_{C} {V}_{CN} )}{jω ( {C}_{A} + {C}_{B} + {C}_{C} ) + 1 / {R}_{N}} ,$$
wherein:
for a first phase of the electrical power system, V_{AG} is the line voltage, V_{A}, is the line-to-neutral voltage, and C_{A} is the charging capacitance;
for a second phase of the electrical power system, V_{BG} is the line voltage, V_{BN} is the line-to-neutral voltage, and C_{B} is the charging capacitance;
for a third phase of the electrical power system, V_{CG} is the line voltage, V_{CN} is the line-to-neutral voltage, and C_{C} is the charging capacitance;
j=\sqrt{−1};
R_{N} is the value of the neutral resistor; and
ω=2πf , where if is the frequency of the electrical power system.

13. The apparatus of claim 12, wherein the processor determines the phase charging current for each phase by solving the following equations:
the phase charging current for the first phase I_{CA}=V_{AC}×jωC_{A};
the phase charging current for the second phase I_{CB}=V_{BG}×jωC_{B}; and
the phase charging current for the third phase I_{CC}=V_{CG}×jωC_{C}.

14. The apparatus of claim 11, wherein the processor determines the system charging current by taking a vector sum of the phase charging currents.

15. The apparatus of claim 11, further comprising an output module having a fault output signal, wherein:
the processor determines the neutral current in the neutral resistor either based on the neutral current measured by the input module or based on the neutral voltage and the value of the neutral resistor;
the output module is electrically coupled to the processor such that the processor sets a state of the fault output signal;
the processor determines a neutral current threshold based on the system charging current; and
the processor sets the state of the fault output signal based whether the neutral current exceeds the neutral current threshold.

16. The apparatus of claim 15, wherein the processor determines the neutral current threshold based on a peak average value of the system charging current, wherein the peak average value is determined over an averaging time period.

17. The apparatus of claim 15, wherein the processor determines the neutral current threshold to be the system charging current multiplied by a number greater than 1.

18. The apparatus of claim 15, wherein the processor determines the state of the fault output signal based on whether the neutral current exceeds the neutral current threshold for more than a predetermined time period.

19. The apparatus of claim 18, wherein the predetermined time period is based on an amount of current by which the neutral current exceeds the neutral current threshold.

20. The apparatus of claim 11, further comprising an output module having a neutral resistor adjustment signal electrically coupled to the neutral resistor, wherein:
the output module is electrically coupled to the processor such that the processor sets a state of the neutral resistor adjustment signal, wherein the neutral resistor adjustment signal determines the value of the neutral resistor; and
the processor sets the value of the neutral resistor based on the system charging current.

21. The apparatus of claim 11, wherein:
the processor determines the neutral current in the neutral resistor either based on the neutral current measured by the input module or based on the neutral voltage and the value of the neutral resistor;
the input module measures a fault current in a fault resistor electrically coupling one phase of the electrical power system to the ground;
the processor reads the fault current from the input module; and
the processor determines the system charging current based on the neutral current and the fault current.

22. The apparatus of claim 11, further comprising a communication module electrically coupled to the processor and to a second apparatus such that the processor sends data related to the electrical power system to the second apparatus and receives data from the second apparatus.

23. An apparatus for determining a system charging current in an electrical power system having three phases, a plurality of feeders, a feeder current sensor for each of the plurality of feeders, a ground, a neutral, and a neutral resistor electrically coupling the neutral to the ground, wherein one phase of the electrical power system has a fault to the ground such that the fault is not in disposed any of the plurality of feeders, the apparatus comprising an input module and a processor, wherein:
the input module is configured to be electrically coupled to the feeder current sensor for each of the plurality of feeders such that the input module measures a net feeder current for each of the plurality of feeders;
the input module is electrically coupled to the processor such that the processor reads the net feeder current for each of the plurality of feeders; and
the processor determines the system charging current based on the net feeder current for each of the plurality of feeders.

24. The apparatus of claim 23, wherein the processor determines the system charging current based on a sum of the net feeder current for each of the plurality of feeders.

25. The apparatus of claim 23, further comprising an output module having a neutral resistor adjustment signal electrically coupled to the neutral resistor, wherein:
the output module is electrically coupled to the processor such that the processor sets a state of the neutral resistor adjustment signal, wherein the neutral resistor adjustment signal determines a value of the neutral resistor; and
the processor sets the value of the neutral resistor based on the system charging current.

26. An apparatus for determining a system charging current in an electrical power system having three phases, a plurality of feeders, a feeder current sensor for each of the plurality of feeders, a ground, a neutral, and a neutral resistor electrically coupling the neutral to the ground, wherein one phase of one of the plurality of feeders has a fault to the ground, the apparatus comprising an input module and a processor, wherein:
the input module is configured to be electrically coupled to the feeder current sensor for each of the plurality of feeders and to the neutral or a neutral current sensor;
the input module measures a net feeder current for each of the plurality of feeders based on the feeder current sensor for each of the plurality of feeders;
the input module measures a neutral voltage or a neutral current based on the neutral current sensor;
the input module is electrically coupled to the processor such that the processor reads the net feeder current for each of the plurality of feeders and the neutral voltage or the neutral current;
the processor determines the neutral current in the neutral resistor either based on the neutral current measured by the input module or based on the neutral voltage and a value of the neutral resistor; and
the processor determines the system charging current based on the net feeder current for each of the plurality of feeders and the neutral current.

27. The apparatus of claim 26, wherein the processor determines which feeder has the fault by comparing phase angles of the net feeder current for each of the plurality of feeders and the neutral current.

28. The apparatus of claim 27, wherein the processor determines a feeder charging current, for feeders not having the fault, is the net feeder current measured by the input module.

29. The apparatus of claim 27, wherein the processor determines the system charging current based on the net feeder current feeder for the feeder having the fault and the neutral current.

30. The apparatus of claim 29, wherein, the feeder charging current for the feeder having the fault is the system charging current minus a sum of the net feeder current for each of the feeders not having the fault.
